(19) United States
(12) Patent Application Publication
(10) Pub. No.: US 2025/0212638 A1
(43) Pub. Date: Jun. 26, 2025

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: CHOLONG WON, Yongin-si (KR); HEEJU WOO, Yongin-si (KR)

(21) Appl. No.: 18/985,596

(22) Filed: Dec. 18, 2024

(30) Foreign Application Priority Data
Dec. 26, 2023 (KR) 10-2023-0191924

(51) Int. Cl. H10K 59/131

(52) U.S. Cl. CPC H10K 59/131

(57) ABSTRACT

A display device includes a substrate including a display area and a peripheral area located around the display area. A plurality of pixels is disposed in the display area. A pad electrode is disposed on the substrate in the peripheral area. A bump portion is disposed on the pad electrode. The bump portion includes a first metal portion. A first polymer is disposed on the first metal portion. The first polymer has a hole defined in a center of the first polymer. A second polymer is disposed inside the hole of the first polymer. A second metal portion is disposed on the first metal portion. The second metal portion covers the first polymer and the second polymer. The second metal portion is electrically connected to the first metal portion.

### CROSS-REFERENCE TO RELATED APPLICATION

This application claims priority under 35 U.S.C. § 119 to Korean Patent Application No. 10-2023-0191924, filed on Dec. 26, 2023 in the Korean Intellectual Property Office, the disclosure of which is incorporated by reference in its entirety herein.

### 1. Technical Field

Embodiments of the present disclosure relate to a display device and an electronic device including the same. More particularly, embodiments of the present disclosure relate to the display device and the electronic device including the same for providing visual information.

### 2. Discussion of Related Art

An anisotropic conductive film (hereinafter referred to as ACF) is used to bond various electronic components to each other. However, as the distance between the pads of electronic components decreases, there is an increase in electrical short circuits between pads due to conductive particles of the ACF, or the number of conductive particles pressed on the pads is not constant, causing non-uniform electrical conductivity problems. This problem of the ACF may occur due to the moving of conductive particles distributed inside an adhesive during the bonding process.

Methods for fixing conductive polymer bumps with structures similar to conductive particles to the chip's pad have been proposed to compensate for ACF's problems. When the polymer bump is fixed to the chip's pad in this manner, the polymer bump has advantages that the polymer bump does not move during the bonding process and an electrical conductivity is constant.

### SUMMARY

An aspect of embodiments of the present disclosure is to provide a display device with increased reliability.

According to an embodiment of the present disclosure, a display device includes a substrate including a display area and a peripheral area located around the display area. A plurality of pixels is disposed in the display area. A pad electrode is disposed on the substrate in the peripheral area. A bump portion is disposed on the pad electrode. The bump portion includes a first metal portion. A first polymer is disposed on the first metal portion. The first polymer has a hole defined in a center of the first polymer. A second polymer is disposed inside the hole of the first polymer. A second metal portion is disposed on the first metal portion. The second metal portion covers the first polymer and the second polymer. The second metal portion is electrically connected to the first metal portion.

In an embodiment, the first polymer may include a negative photoresist material.

In an embodiment, the second polymer may include a positive photoresist material.

In an embodiment, the first polymer may have a first length and a second length. The first length may extend in a first direction in a plan view. The second length may extend in a second direction intersecting the first direction in the plan view. Each of the first length and the second length may be in a range of about 2 μm to about 5 μm.

In an embodiment, the first polymer may have a third length extending in a vertical direction intersecting a first direction and a second direction. The third length is about 3 μm or less.

In an embodiment, the second polymer may have a convex semicircular shape in a cross-sectional view that protrudes outside the hole of the first polymer.

In an embodiment, the bump portion may have a circular shape in a plan view.

In an embodiment, the display device may further include a driving driver disposed on the second metal portion. The second metal portion and the driving driver may be in direct contact with each other.

In an embodiment, the display device may further include a non-conductive film between the driving driver and the second metal portion in a cross-sectional view.

According to an embodiment of the present disclosure, a display device includes a substrate including a display area and a peripheral area located around the display area. A plurality of pixels is disposed in the display area. A pad electrode is disposed on the substrate in the peripheral area. A bump portion is disposed on the pad electrode. The bump portion includes a first polymer having a hole defined in a center of the first polymer. A second polymer is disposed in the hole of the first polymer. A first metal portion is disposed on the second polymer and covers the first polymer and the second polymer.

In an embodiment, the first polymer may include a negative photoresist material.

In an embodiment, the second polymer may include a positive photoresist material.

In an embodiment, the first polymer may have a first length and a second length. The first length may extend in a first direction in a plan view. The second length may extend in a second direction intersecting the first direction in the plan view. Each of the first length and the second length may be in a range of about 2 μm to about 5 μm.

In an embodiment, the first polymer may have a third length extending in a vertical direction intersecting a first direction and a second direction. The third length may be about 3 μm or less.

In an embodiment, the second polymer may have a convex semicircular shape in a cross-sectional view that protrudes outside the hole of the first polymer.

In an embodiment, the display device may further include a second metal portion covering the first metal portion.

In an embodiment, the first metal portion and the second metal portion may be electrically connected to each other.

In an embodiment, the bump portion may have a circular shape in a plan view.

In an embodiment, the display device may further include a driving driver disposed on the first metal portion. The first metal portion and the driving driver may be in direct contact with each other.

In an embodiment, the display device may further include a non-conductive film between the driving driver and the first metal portion in a cross-sectional view.

According to an embodiment of the present disclosure, an electronic device includes a display device and a processor that drives the display device, and wherein the display device includes a substrate including a display area and a peripheral area located around the display area, a plurality of pixels disposed in the display area, a pad electrode disposed on the substrate in the peripheral area, and a bump portion disposed on the pad electrode, and the bump portion including a first metal portion, a first polymer disposed on the first metal portion, the first polymer having a hole defined in a center of the first polymer, a second polymer disposed in the hole of the first polymer, and a second metal portion disposed on the first metal portion, the second metal portion covering the first polymer and the second polymer, wherein the second metal portion is electrically connected to the first metal portion.

A display device may include a substrate including a display area and a peripheral area located around the display area, a plurality of pixels disposed in the display area, a pad electrode disposed in the peripheral area and disposed on the substrate, and a bump portion disposed on the pad electrode and the bump portion may include a first metal portion, a first polymer disposed on the first metal portion and defining a hole at a center, a second polymer disposed inside the hole of the first polymer, and a second metal portion disposed on the first metal portion, covering the first polymer and the second polymer, and electrically connected to the first metal portion.

Therefore, since an upper part of the second polymer has a convex shape, reliable initial resistance may be secured when the bump portion contacts with the driving driver, and the first polymer supports the second polymer to maintain the shape of the bump portion, thereby maintaining reliable resistance.

In addition, since the bump portion and the driving driver are in direct contact without a use of conductive balls, leakage current between adjacent pad portions may be prevented. Accordingly, even when display devices are miniaturized, reliability may be secured when applying a driving signal.

### BRIEF DESCRIPTION OF THE DRAWINGS

The accompanying drawings, which are included to provide a further understanding of the present disclosure and are incorporated in and constitute a part of this specification, illustrate non-limiting embodiments of the present disclosure together with the description.

FIGS. 1 and 2 are perspective views of a display device according to embodiments of the present disclosure.

FIG. 3 is a cross-sectional view taken along line I-I′ of FIG. 2 according to an embodiment of the present disclosure.

FIG. 4 is an enlarged view of portion A of FIG. 2 according to an embodiment of the present disclosure.

FIG. 5 is an enlarged view of part B of FIG. 4 according to an embodiment of the present disclosure.

FIG. 6 is a cross-sectional view taken along line II-II′ of FIG. 5 according to an embodiment of the present disclosure.

FIGS. 7 to 14 are cross-sectional views showing a method for manufacturing the pad portion of FIG. 6 according to embodiments of the present disclosure.

FIG. 15 is a cross-sectional view showing an example of a bump portion included in a display device according to an embodiment of the present disclosure.

FIG. 16 is a cross-sectional view showing a bump portion included in a display device according to an embodiment of the present disclosure.

FIG. 17 is a block-diagram showing an electronic device according to an embodiment of the present disclosure.

FIG. 18 is a schematic diagram of the electronic device according to various embodiments of FIG. 17.

### DETAILED DESCRIPTION OF EMBODIMENTS

Illustrative, non-limiting embodiments of the present disclosure will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2. However, embodiments of the present disclosure are not necessarily limited thereto and the first to third directions D1 to D3 may intersect each other at various different angles.

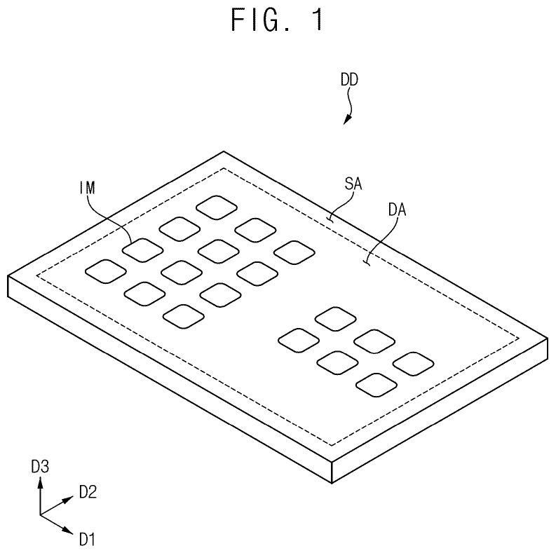

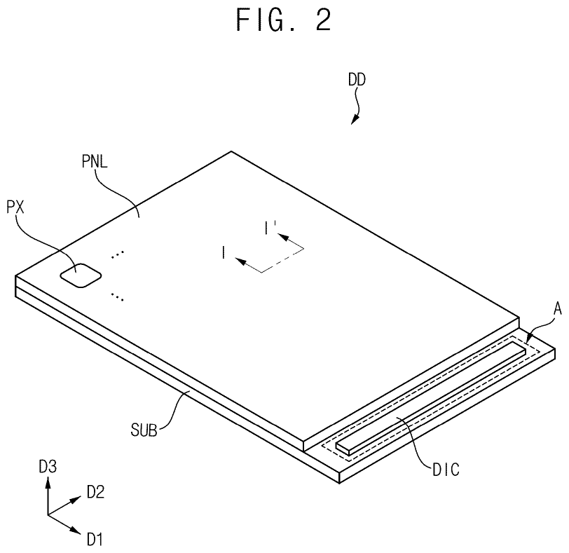

FIGS. 1 and 2 are perspective views of a display device according to embodiments of the present disclosure.

Referring to FIG. 1, a display device DD may include a display area DA and a peripheral area SA. The display area DA may be surrounded by the peripheral area SA (e.g., in the first and/or second directions D1, D2).

The display area DA may be an area that may display an image by generating light or adjusting a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM, such as moving and/or still images. Users may receive information from the display device DD through the plurality of images IM.

Referring further to FIG. 2, in an embodiment the display device DD may include a substrate SUB, a display panel PNL, and a driving driver DIC.

In an embodiment, the display panel PNL may cover a partial area of the substrate SUB. The display panel PNL may be disposed in an area corresponding to the display area DA.

The driving driver DIC may be disposed in an area that does not overlap the display panel PNL in a plan view (e.g., in a plane defined in the first and second directions D1, D2). The driving driver DIC may be disposed in the peripheral area SA of the display device DD. The driving driver DIC may drive the display panel PNL so that the display device DD may provide visual information to a user. In an embodiment, the driving driver DIC may be a data driving driver.

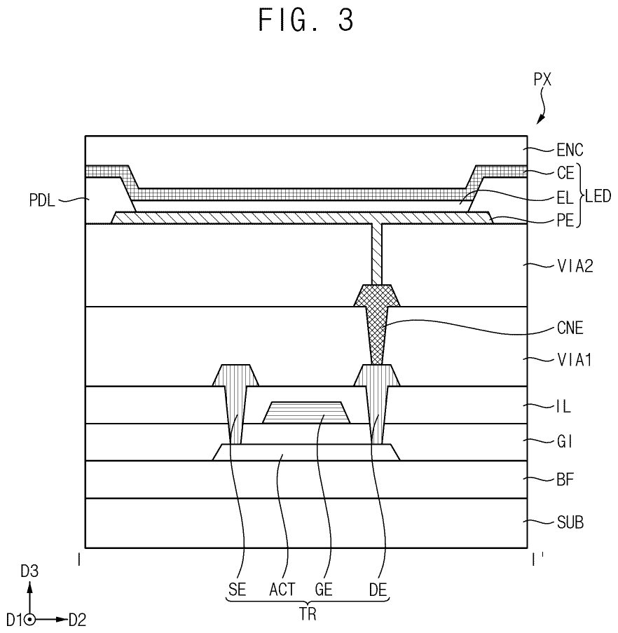

FIG. 3 is a cross-sectional view taken along line I-I′ of FIG. 2.

Referring to FIGS. 1, 2, and 3, in an embodiment a pixel PX may include the substrate SUB, a buffer layer BF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC.

In an embodiment, the transistor TR may include an active layer ACT, a gate electrode GE, a source electrode SE, and a drain electrode DE. The light emitting diode LED may include a pixel electrode PE, a light emitting layer EL, and a common electrode CE.

In an embodiment, the substrate SUB may include a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BF may be disposed on the substrate SUB (e.g., disposed directly thereon in the third direction D3). The buffer layer BF may prevent impurities such as oxygen and moisture from penetrating into an upper part of the substrate SUB. The buffer layer BF may include an inorganic insulating material. In an embodiment, the buffer layer BF may be formed entirely in the display area DA and the peripheral area SA.

The active layer ACT may be disposed on the buffer layer BF (e.g., disposed directly thereon in the third direction D3). In an embodiment, the active layer ACT may include an oxide semiconductor, a silicon semiconductor, an organic semiconductor, etc. For example, in an embodiment the oxide semiconductor may include at least one compound selected from a group including indium (In), gallium (Ga), tin (Sn), zirconium (Zr), vanadium (V), hafnium (Hf), cadmium (Cd), germanium GE, and chromium. (Cr), titanium (Ti), and zinc (Zn). The silicon semiconductor may include amorphous silicon, polycrystalline silicon, etc. The active layer ACT may include a source region, a drain region, and a channel region located between the source region and the drain region.

The gate insulating layer GI may be disposed on the buffer layer BF (e.g., disposed directly thereon in the third direction D3). For example, the gate insulating layer GI may cover the active layer ACT on the buffer layer BF. In an embodiment, the gate insulating layer GI may directly contact an upper surface and lateral side surfaces of the active layer ACT. The gate insulating layer GI may include an inorganic insulating material. In an embodiment, the gate insulating layer GI may be formed entirely in the display area DA and the peripheral area SA.

The gate electrode GE may be disposed on the gate insulating layer GI (e.g., disposed directly thereon in the third direction D3). In an embodiment, the gate electrode GE may overlap the channel region of the active layer ACT (e.g., in the third direction D3). The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (Pt), nickel (Ni), titanium (Ti), and palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide. (GaO), indium zinc oxide (IZO), etc. These materials may be used alone or in combination with each other. Alternatively, the gate electrode GE may have a single-layer structure or a multi-layer structure including a plurality of conductive layers.

The interlayer insulating layer IL may be disposed on the gate electrode GE. For example, the interlayer insulating layer IL may cover the gate electrode GE on the gate insulating layer GI. In an embodiment, the interlayer insulating layer IL may directly contact an upper surface and lateral side surfaces of the gate electrode GE. The interlayer insulating layer IL may include an inorganic insulating material. In an embodiment, the interlayer insulating layer IL may be formed entirely in the display area DA and the peripheral area SA.

The source electrode SE and the drain electrode DE may be disposed on the interlayer insulating layer IL (e.g., disposed directly thereon in the third direction D3). The source electrode SE and the drain electrode DE may be respectively connected to (e.g., directly connected thereto) the active layer ACT. In an embodiment, the source electrode SE may be connected to (e.g., directly connected thereto) a source region of the active layer ACT through a contact hole formed in the interlayer insulating layer IL and the gate insulating layer GI, and the drain electrode DE may be connected to (e.g., directly connected thereto) a drain region of the active layer ACT through a contact hole formed in the interlayer insulating layer IL and the gate insulating layer GI. Each of the source electrode SE and the drain electrode DE may include a conductive material.

The first via layer VIA1 may be disposed on (e.g. disposed directly thereon) the source electrode SE and the drain electrode DE. For example, the first via layer VIA1 may cover the source electrode SE and the drain electrode DE on the interlayer insulating layer IL. The first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1 (e.g., disposed directly thereon in the third direction D3). In an embodiment, the connection electrode CNE may transmit a signal transmitted from the transistor TR to the light emitting diode LED. In an embodiment, the connection electrode CNE may penetrate the first via layer VIA1 and be connected to (e.g., directly connected thereto) the drain electrode DE. In an embodiment, the connection electrode CNE may include metal, alloy, metal nitride, conductive metal oxide, transparent conductive material, etc. These materials be used alone or in combination with each other. However, embodiments of the present disclosure are not necessarily limited thereto.

The second via layer VIA2 may be disposed on (e.g., disposed directly thereon) the connection electrode CNE. For example, the second via layer VIA2 may cover the connection electrode CNE on the first via layer VIA1. In an embodiment, the second via layer VIA2 may include substantially a same material as the first via layer VIA1.

The pixel electrode PE may be disposed on the second via layer VIA2 (e.g., disposed directly thereon in the third direction D3). The pixel electrode PE may include a conductive material. The pixel electrode PE may penetrate the second via layer VIA2 to be connected to (e.g., directly connected to) the connection electrode CNE. In an embodiment, the pixel electrode PE may be connected to (e.g., electrically connected thereto) the drain electrode DE through the connection electrode CNE formed in the first via layer VIA1. Accordingly, the pixel electrode PE may be electrically connected to the transistor TR.

The pixel defining layer PDL may be disposed on (e.g., disposed directly thereon) the pixel electrode PE. In an embodiment, the pixel defining layer PDL may be disposed on a side of the pixel electrode PE (e.g., lateral edges of the pixel electrode PE), and at least a portion of the pixel electrode PE may be exposed, such as a central portion of the pixel electrode PE. The pixel defining layer PDL may include an inorganic insulating material or an organic insulating material.

The light emitting layer EL may be disposed on the pixel electrode PE. The light emitting layer EL may be disposed between the pixel defining layers PDL. For example, the light emitting layer EL may be disposed in an opening defined by the pixel defining layer PDL. The light emitting layer EL may include at least one of organic light emitting material and/or quantum dots. However, embodiments of the present disclosure are not necessarily limited thereto.

The common electrode CE may be disposed on the light emitting layer EL. The common electrode CE may also be disposed on the pixel defining layer PDL. The common electrode CE may include a conductive material. For example, the common electrode CE may transmit an ELVSS signal.

In an embodiment, the common electrode CE may be a plate electrode that covers an entire display area DA. For example, the common electrode CE may be an electrode disposed along the first direction D1 and the second direction D2 and be commonly disposed in a plurality of light emitting diodes LED.

The encapsulation layer ENC may be disposed on the common electrode CE (e.g., disposed directly thereon in the third direction D3). The encapsulation layer ENC may include at least one inorganic encapsulation layer and at least one organic encapsulation layer. In an embodiment, the inorganic encapsulation layer and the organic encapsulation layer may be alternately disposed (e.g., in the third direction D3).

For example, the organic encapsulation layer may include a cured polymer such as polyacrylate, epoxy resin, silicone resin, etc. For example, the inorganic thin film may include silicon oxide, silicon nitride, silicon carbide, aluminum oxide, tantalum oxide, hafnium oxide, zirconium oxide, titanium oxide, etc.

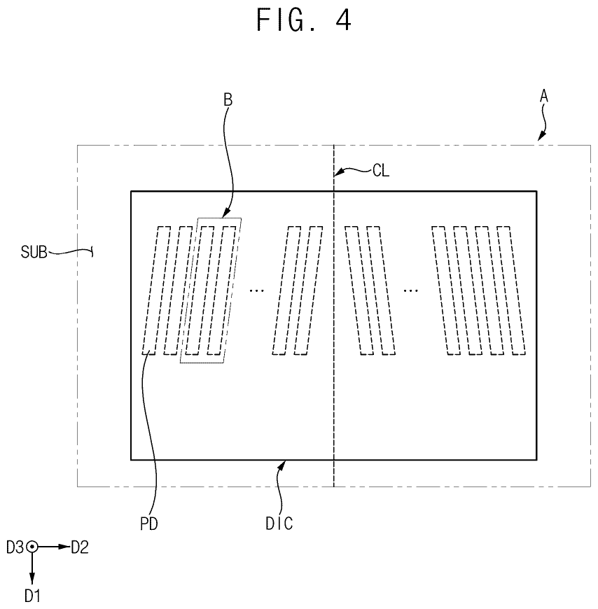

FIG. 4 is an enlarged view of portion A of FIG. 2.

Referring to FIG. 4, the driving driver DIC may be disposed on the substrate SUB. For example, pad portions PD may be disposed on the substrate SUB and below the driving driver DIC. For example, the pad portions PD may be arranged along the second direction D2 and be spaced apart from each other.

A center line CL may be defined at a center of the driving driver DIC (e.g., in the second direction D2). For example, the center line CL may be an imaginary line that passes through the center of the driving driver DIC (e.g., in the second direction D2) and extends in the first direction D1. The pad portions PD may be arranged symmetrically with respect to the center line CL.

In FIG. 4, the pad portions PD are shown to be arranged at a constant angle with respect to the center line CL. However, embodiments of the present disclosure are not necessarily limited thereto. In some embodiments the pad portions PD may be arranged parallel to the center line CL. For example, the pad portions PD may be arranged in parallel along the first direction D1. In addition, the pad portions PD are shown to be symmetrical with respect to the center line CL. However, embodiments of the present disclosure are not necessarily limited thereto.

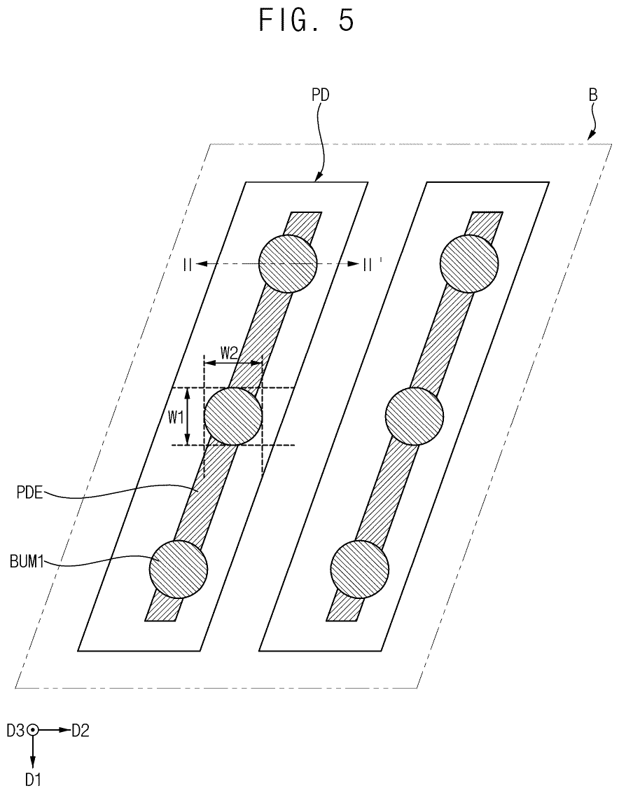

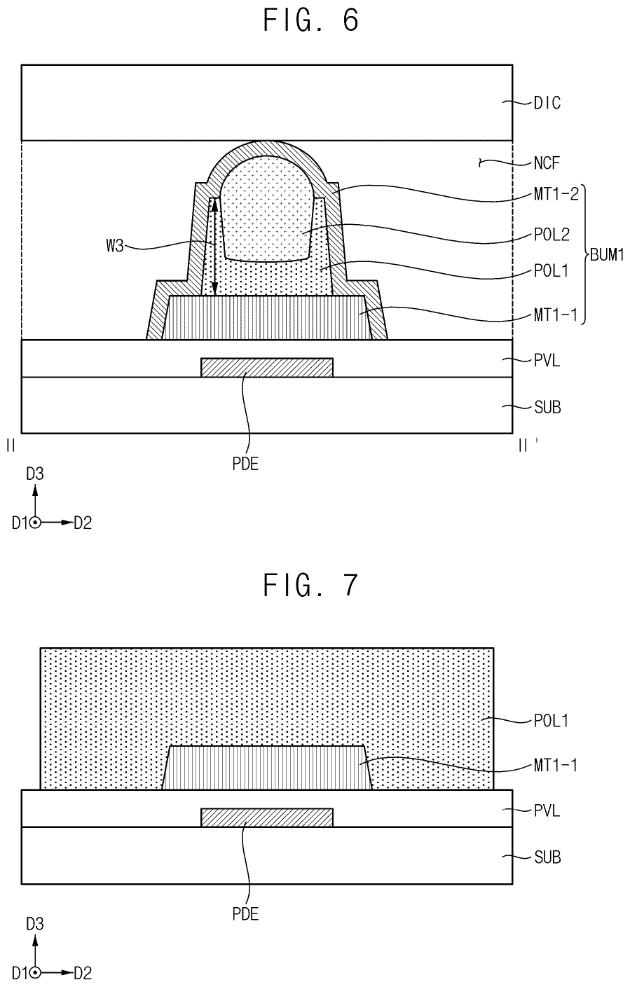

FIG. 5 is an enlarged view of part B of FIG. 4. FIG. 6 is a cross-sectional view taken along line II-II′ of FIG. 5.

Referring to FIGS. 5 and 6, the pad portions PD may include a pad electrode PDE and a first bump portion BUM1.

In an embodiment, like the pad portions PD, as shown in FIG. 5, the pad electrode PDE may have a shape such as a square or parallelogram in a plan view. As shown in FIG. 6, the pad electrode PDE may be disposed on the substrate SUB (e.g., disposed directly thereon in the third direction D3) in the peripheral area SA. The pad electrode PDE may transmit a signal transmitted from the first bump portion BUM1 to the pixel (e.g., the pixel PX in FIG. 2). The pad electrode PDE may include a metal material.

A protective layer PVL may be disposed on (e.g., disposed directly thereon) the pad electrode PDE. For example, the protective layer PVL may be disposed on the substrate SUB and cover the pad electrode PDE. In an embodiment, a contact hole may be defined in the protective layer PVL in a third direction D3 that intersects the first direction D1. As the contact hole is defined in the protective layer PVL, the first bump portion BUM1 and the pad electrode PDE may be electrically connected to each other. For example, in an embodiment the protective layer PVL may include a polymer material such as polyimide-based, polybenzoxazole-based, acrylic-based, phenol-based, silicone-based, silicon-modified polyimide-based, epoxy-based, and a photosensitive organic material. These materials may be used alone or in combination with each other. However, embodiments of the present disclosure are not necessarily limited thereto.

The first bump portion BUM1 may be disposed on the protective layer PVL (e.g., disposed directly thereon in the third direction D3). In an embodiment, the first bump portion BUM1 may include a (1-1)th metal portion MT1-1 (e.g., a first metal portion), a (1-2)th metal portion MT1-2 (e.g., a second metal portion), a first polymer POL1, and a second polymer POL2.

In an embodiment, as shown in FIG. 5, the first bump portion BUM1 may have a first length W1 extending in the first direction D1 and a second length W2 extending in the second direction D2 in a plan view. In an embodiment, each of the first length W1 and the second length W2 may be in a range of about 2 μm to about 5 μm. In an embodiment in which each of the first length W1 and the second length W2 is greater than the range described above, an area where the first bump portion BUM1 contacts the driving driver DIC in a plan view becomes wider, so that an initial resistance may increase. Conversely, in an embodiment in which each of the first length W1 and the second length W2 is less than the above-described range, the first polymer POL1 may not be possible to implement.

In an embodiment, the first bump portion BUM1 may have a circular shape in a plan view. However, embodiments of the present disclosure are not necessarily limited thereto. In an embodiment, a planar shape of the first bump portion BUM1 may include various other shapes, such as a polygon, an oval, etc.

The (1-1)th metal portion MT1-1 may be disposed on the protective layer PVL (e.g., disposed directly thereon in the third direction D3). The (1-1)th metal portion MT1-1 may be electrically connected to the pad electrode PDE through the contact hole of the protective layer PVL.

The first polymer POL1 may be disposed on the (1-1)th metal portion MT1-1 (e.g., disposed directly thereon in the third direction D3). In an embodiment, the first polymer POL1 may have a hole defined at a center. For example, a concave hole may be defined in a center of the first polymer POL1 in a direction opposite to the third direction D3. For example, the first polymer POL1 may have a bowl shape open in the third direction D3 in a cross-sectional view.

In an embodiment, the first polymer POL1 may include a negative photoresist material. For example, the first polymer POL1 may include an epoxy-based polymer or an off-stoichiometry thiol-enes (OSTE) polymer. These materials may be used alone or in combination with each other. However, embodiments of the present disclosure are not necessarily limited thereto.

In an embodiment, the first polymer POL1 may have a third length W3 in the third direction D3 (e.g., a vertical direction). The third length W3 may be a maximum length of the first polymer POL1 disposed at the edges of the first polymer POL1 which surround the center of the first polymer POL1 having the concave hole. In an embodiment, the third length W3 may be less than about 5 μm. For example, the third length W3 may be less than about 3 μm. If the third length W3 is greater than the range described above, a stability of the first bump portion BUM1 may decrease or a resistance between the first bump portion BUM1 and the driving driver DIC may increase.

The second polymer POL2 may be disposed on (e.g., disposed directly thereon) the first polymer POL1. In an embodiment, the second polymer POL2 may be disposed inside the hole defined in the first polymer POL1. The second polymer POL2 may be disposed inside the concave hole of the first polymer POL1 and protruding outside of the concave hole of the first polymer POL1. The second polymer POL2 may have a semicircular shape that is convex in the third direction D3 in a cross-sectional view (e.g., a convex semicircular shape). The convex semicircular-shaped portion of the second polymer POL2 may protrude outside of the concave hole defined in the first polymer POL1 and the portion of the second polymer POL2 inside the concave hole may have a shape corresponding to the concave hole.

In an embodiment, the second polymer POL2 may include a positive photoresist material. For example, the second polymer POL2 may include diazonaphthoquinone, maleic anhydride/norbornene copolymer, hydroxystyrene/acrylate copolymer, methacrylate copolymer, diazonaphthoquinone (DNQ), and novolac resin. These materials may be used alone or in combination with each other. However, embodiments of the present disclosure are not necessarily limited thereto.

The (1-2)th metal portion MT1-2 may be disposed on (e.g., disposed directly thereon) the (1-1)th metal portion MT1-1. For example, the (1-2)th metal portion MT1-2 may be disposed on the (1-1)th metal portion MT1-1 and cover the first polymer POL1 and the second polymer POL2. As the (1-1)th metal portion MT1-1 and the (1-2)th metal portion MT1-2 directly contact each other, the (1-1)th metal portion MT1-1 and the (1-2)th metal portion MT1-2 may be electrically connected to each other.

The driving driver DIC may be disposed on the (1-2)th metal portion MT1-2 (e.g., disposed directly thereon in the third direction D3). For example, the driving driver DIC may be electrically connected to the first bump portion BUM1 by directly contacting the (1-2)th metal portion MT1-2. As the (1-2)th metal portion MT1-2 and the driving driver DIC are electrically connected by direct contact, a conductive ball may be omitted between the protective layer PVL and the driving driver DIC in a cross-sectional view. For example, a non-conductive film NCF may be disposed between the protective layer PVL and the driving driver DIC in a cross-section. The non-conductive film NCF may be arranged to be directly between the protective layer PVL and the driving driver DIC in the third direction D3.

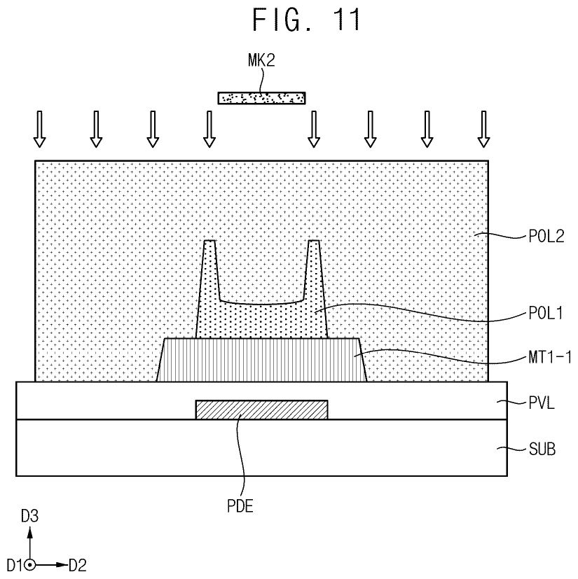

FIGS. 7 to 14 are cross-sectional views showing a method for manufacturing the pad portion of FIG. 6.

Referring to FIGS. 7, 8, and 9, the first polymer POL1 may be formed on the substrate SUB, the pad electrode PDE, the protective layer PVL, and the (1-1)th metal portion MT1-1. In an embodiment, the first polymer POL1 may include a negative photoresist material. In an embodiment, an exposure process, a development process, etc. may be performed on the first polymer POL1 according to a first mask MK1. Through above processes, the first polymer POL1 may be formed as a bowl shape with the hole defined at the center, as shown in FIG. 9.

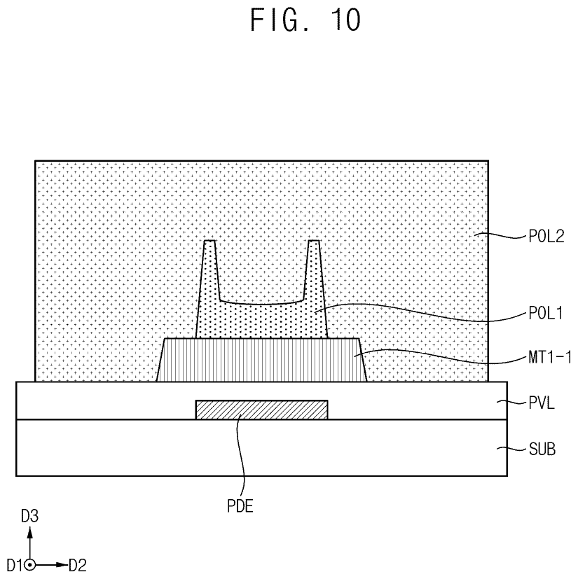

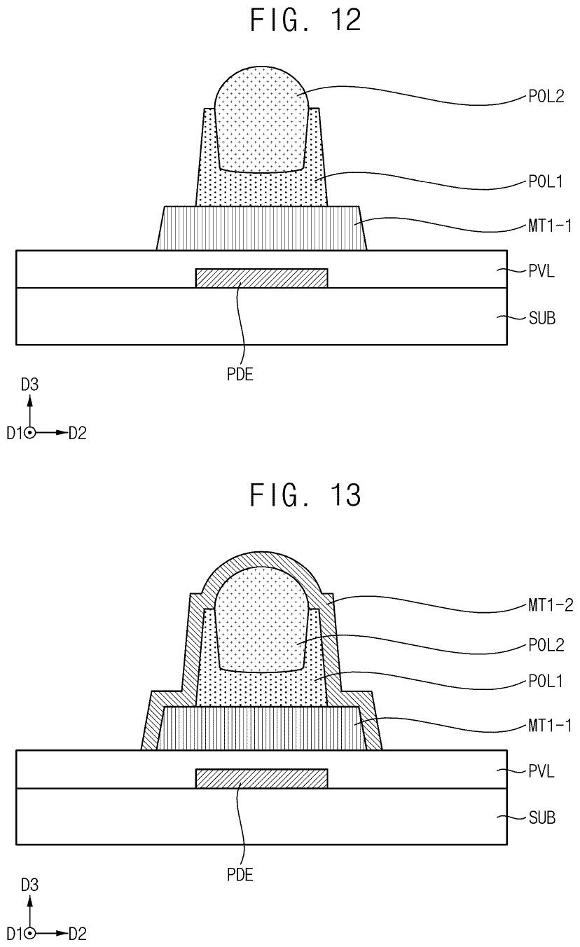

Referring further to FIGS. 10, 11, and 12, the second polymer POL2 may be formed on (e.g., formed directly thereon) the first polymer POL1 to cover the first polymer POL1. In an embodiment, the second polymer POL2 may include a positive photoresist material. An exposure process, a development process, etc. may be performed on the second polymer POL2 according to a second mask MK2. As a result of the above processes, the second polymer POL2 may be formed inside the first polymer POL1 as shown in FIG. 12. For example, through the above process, the second polymer POL2 may be formed to have a semicircular shape that is convex in the third direction D3 in a cross section.

Referring further to FIG. 13, the (1-2)th metal portion MT1-2 may be formed on (e.g., formed directly thereon) the second polymer POL2. In an embodiment, the (1-2)th metal portion MT1-2 may be formed on the (1-1)th metal portion MT1-1, cover the first polymer POL1 and the second polymer POL2, and be electrically connected to (and physically directly connected thereto) the (1-1)th metal portion MT1-1.

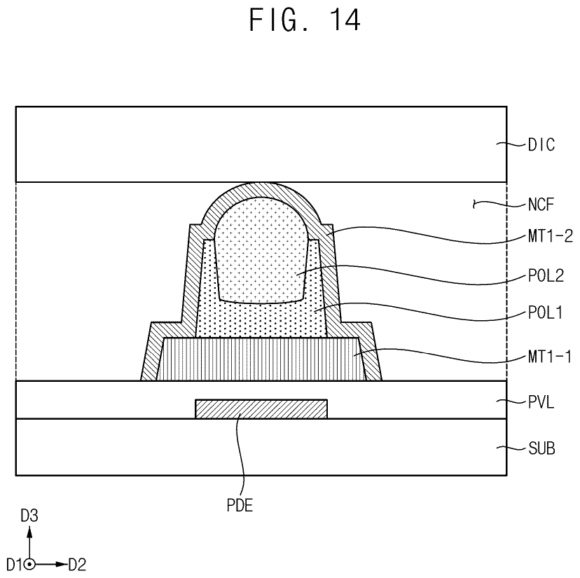

Referring further to FIG. 14, the non-conductive film NCF may be formed covering the protective layer PVL and the (1-2)th metal portion MT1-2. In an embodiment, the non-conductive film NCF may not include conductive balls.

Thereafter, the driving driver DIC may be formed on (e.g., formed directly thereon in the third direction DR3) the non-conductive film NCF and the (1-2)th metal portion MT1-2. In an embodiment, the driving driver DIC may be a data driving driver DIC. The driving driver DIC may directly contact the (1-2)th metal portion MT1-2. As a result, an electrical signal applied from the driving driver DIC may be transmitted to the pad electrode PDE through the first bump portion BUM1.

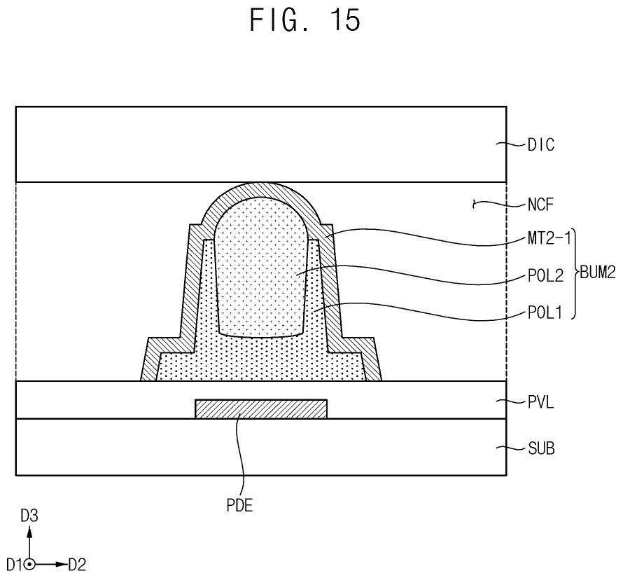

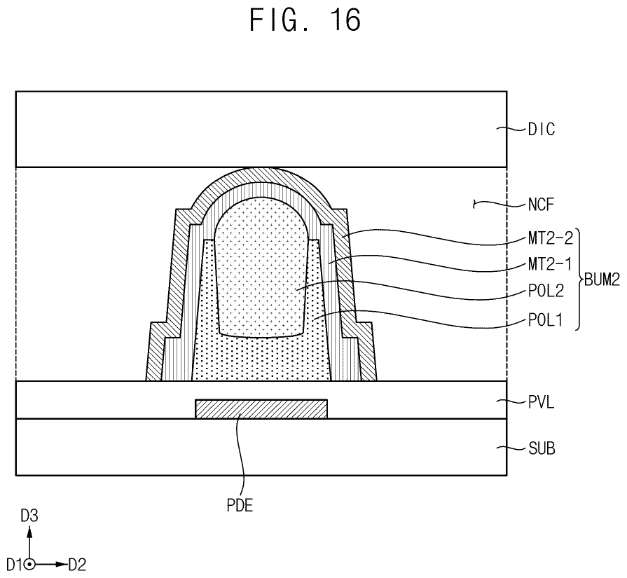

FIG. 15 is a cross-sectional view showing an example of a bump portion included in a display device according to an embodiment of the present disclosure. FIG. 16 is a cross-sectional view showing an example of a bump portion included in a display device according to an embodiment of the present disclosure. The second bump portion BUM2 described with reference to FIGS. 15 and 16 may be substantially same as the first bump portion BUM1 with reference to FIG. 6 except for a (2-1)th metal portion MT2-1 and a (2-2)th metal portion MT2-2 described. Therefore, overlapping descriptions may be omitted or simplified for economy of explanation.

Referring to FIG. 15, in an embodiment the second bump portion BUM2 may include the (2-1)th metal portion MT2-1, the first polymer POL1, and the second polymer POL2.

The first polymer POL1 of the second bump portion BUM2 may be disposed on the protective layer PVL (e.g., disposed directly thereon in the third direction D3). The first polymer POL1 may have a bowl shape open in the third direction D3 in a cross-sectional view. In an embodiment, the first polymer POL1 may include a negative photoresist material.

The second polymer POL2 of the second bump portion BUM2 may be disposed on (e.g., disposed directly thereon) the first polymer POL1. The second polymer POL2 may be disposed inside the first polymer POL1 and may be semicircular shape that is convex in the third direction D3 in a cross-sectional view. In an embodiment, the second polymer POL2 may include a positive photoresist material.

The (2-1)th metal portion MT2-1 may be disposed on (e.g., disposed directly thereon) the second polymer POL2 and may cover the first polymer POL1 and the second polymer POL2. In an embodiment, the (2-1)th metal portion MT2-1 may be electrically connected to the pad electrode PDE through the contact hole defined in the protective layer PVL.

Referring further to FIG. 16, a (2-2)th metal portion MT2-2 may cover the (2-1)th metal portion MT2-1. For example, in an embodiment the (2-2)th metal portion MT2-2 may be formed on (e.g., formed directly thereon) the (2-1)th metal portion MT2-1 and may be electrically connected to the (2-1)th metal portion MT2-1.

As shown in FIG. 16, the (2-2)th metal portion MT2-2 may be in direct contact with the driving driver DIC and the (2-1)th metal portion MT2-1 and the (2-2)th metal portion MT2-2 may apply electrical signals from the driving driver DIC to the pad electrode PDE. In addition, the non-conductive film NCF may be disposed between the driving driver DIC and the (2-1)th metal portion MT2-1 in a cross-sectional view.

As a result, as an upper part of the second polymer POL2 has a convex shape, so that reliable initial resistance may be secured when contacting the driving driver DIC, and as the first polymer POL1 supports the second polymer POL2, a shape of the bump portion may be maintained and reliable resistance may be maintained.

In addition, since the bump portion and the driving driver are in direct contact without a use of conductive balls, and no conductive balls are required, leakage current between adjacent pad portions may be prevented. Accordingly, even when display devices are miniaturized, reliability may be secured when applying a driving signal.

The present disclosure may be applied to a display device and a electronic device including a same. For example, embodiments of the present disclosure may include high-resolution smartphones, mobile phones, smart pads, smart watches, tablet PCs, vehicle navigation systems, televisions, computer monitors, laptops, etc. However, embodiments of the present disclosure are not necessarily limited thereto.

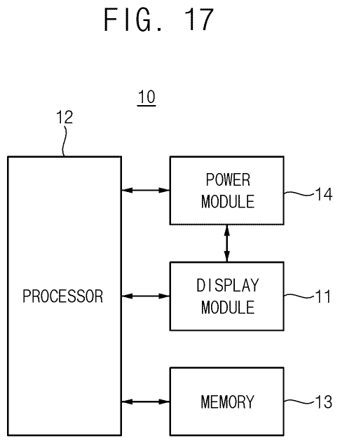

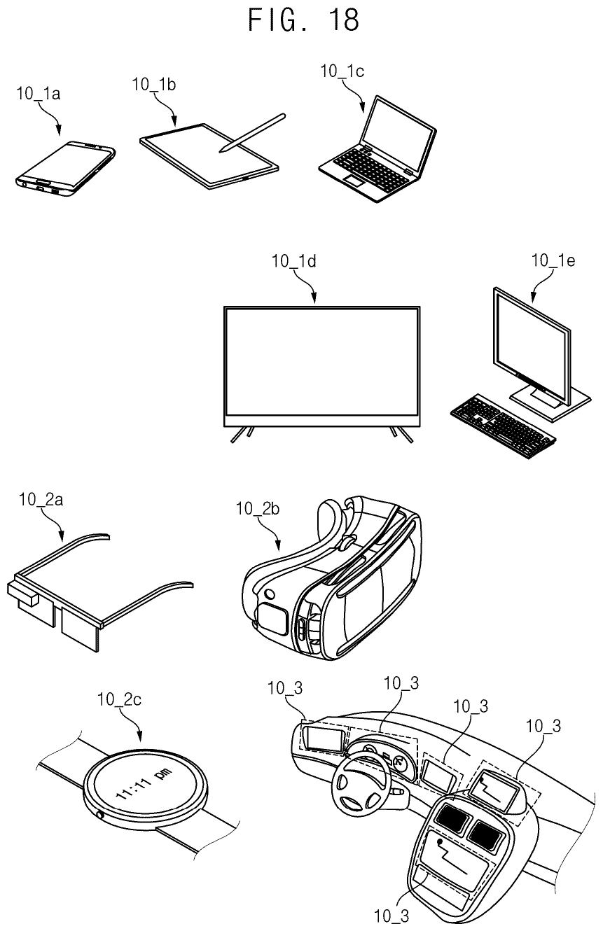

FIG. 17 is a block-diagram showing an electronic device according to an embodiment of the present disclosure.

Referring to FIGS. 1 and 17, the display device DD according to the embodiments may be applied to various electronic devices 10. The electronic device 10 according to an embodiment may include the display device DD, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device DD according to the embodiments described above. In addition, some of the individual modules functionally included in one module may be included in the display device DD, and other parts may be provided separately from the display device DD. For example, the display device DD may include the display module 11, and the processor 12, the memory 13, and the power module 14 may be provided in a form of another device within the electronic device 10 other than the display device DD.

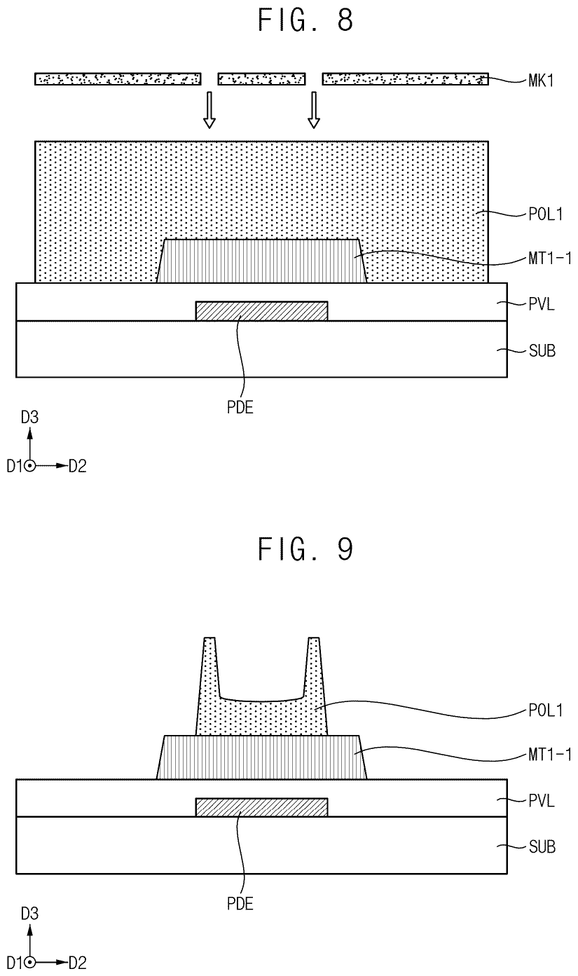

FIG. 18 is a schematic diagram of the electronic device according to various embodiments of FIG. 8.

Referring to FIGS. 17 and 18, various electronic devices 10 to which the display device DD according to the embodiments is applied may include not only image display electronic devices such as a smart phone 10_1a, a tablet PC 10_1b, a laptop 10_1c, a TV 10_1d, a desk monitor 10_1e, but also wearable electronic devices including display modules such as smart glasses 10_2a, a head-mounted display 10_2b, a smart watch 10_2c, etc. and vehicle electronic devices 10_3 including display modules such as a CID (Center Information Display) disclosure on a dashboard, center fascia, or dashboard of a car, and a room mirror display.

However, this is exemplary, and the electronic devices 10 according to the embodiments of the present disclosure are not necessarily limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile

While the disclosure has been particularly shown and described with reference to non-limiting embodiments thereof, it will be understood by those of ordinary skill in the art that various changes in form and details may be made therein without departing from the spirit or scope of the present disclosure.

What is claimed is:

1. A display device comprising:
a substrate including a display area and a peripheral area located around the display area;
a plurality of pixels disposed in the display area;
a pad electrode disposed on the substrate in the peripheral area; and
a bump portion disposed on the pad electrode, and
the bump portion including:
a first metal portion;
a first polymer disposed on the first metal portion, the first polymer having a hole defined in a center of the first polymer;
a second polymer disposed in the hole of the first polymer; and
a second metal portion disposed on the first metal portion, the second metal portion covering the first polymer and the second polymer, wherein the second metal portion is electrically connected to the first metal portion.

2. The display device of claim 1, wherein the first polymer includes a negative photoresist material.

3. The display device of claim 1, wherein the second polymer includes a positive photoresist material.

4. The display device of claim 1, wherein:
the first polymer has a first length and a second length;
the first length extends in a first direction in a plan view;
the second length extends in a second direction intersecting the first direction in the plan view; and
each of the first length and the second length is in a range of about 2 μm to about 5 μm.

5. The display device of claim 1, wherein:
the first polymer has a third length extending in a vertical direction intersecting a first direction and a second direction; and
the third length is about 3 μm or less.

6. The display device of claim 1, wherein the second polymer has a convex semicircular shape in a cross-sectional view that protrudes outside the hole of the first polymer.

7. The display device of claim 1, wherein the bump portion has a circular shape in a plan view.

8. The display device of claim 1, further comprising:
a driving driver disposed on the second metal portion,
wherein the second metal portion and the driving driver are in direct contact with each other.

9. The display device of claim 8, further comprising:
a non-conductive film between the driving driver and the second metal portion in a cross-sectional view.

10. A display device comprising:
a substrate including a display area and a peripheral area located around the display area;
a plurality of pixels disposed in the display area;
a pad electrode disposed on the substrate in the peripheral area; and
a bump portion disposed on the pad electrode, and
the bump portion including:
a first polymer having a hole defined in a center of the first polymer;
a second polymer disposed in the hole of the first polymer; and
a first metal portion disposed on the second polymer and covering the first polymer and the second polymer.

11. The display device of claim 10, wherein the first polymer includes a negative photoresist material.

12. The display device of claim 10, wherein the second polymer includes a positive photoresist material.

13. The display device of claim 10, wherein:
the first polymer has a first length and a second length;
the first length extends in a first direction in a plan view;
the second length extends in a second direction intersecting the first direction in the plan view; and
each of the first length and the second length is in a range of about 2 μm to about 5 μm.

14. The display device of claim 10, wherein:
the first polymer has a third length extending in a vertical direction intersecting a first direction and a second direction; and
the third length is about 3 μm or less.

15. The display device of claim 10, wherein the second polymer has a convex semicircular shape in a cross-sectional view that protrudes outside the hole of the first polymer.

16. The display device of claim 10, further comprising:
a second metal portion covering the first metal portion.

17. The display device of claim 16, wherein the first metal portion and the second metal portion are electrically connected to each other.

18. The display device of claim 10, wherein the bump portion has a circular shape in a plan view.

19. The display device of claim 10, further comprising:
a driving driver disposed on the first metal portion; and
the first metal portion and the driving driver are in direct contact with each other.

20. The display device of claim 19, further comprising:
a non-conductive film between the driving driver and the first metal portion in a cross-sectional view.

21. An electronic device comprising:
a display device; and
a processor that drives the display device, and
wherein the display device includes:
a substrate including a display area and a peripheral area located around the display area;
a plurality of pixels disposed in the display area;
a pad electrode disposed on the substrate in the peripheral area; and
a bump portion disposed on the pad electrode, and
the bump portion including:
a first metal portion;
a first polymer disposed on the first metal portion, the first polymer having a hole defined in a center of the first polymer;
a second polymer disposed in the hole of the first polymer; and
a second metal portion disposed on the first metal portion, the second metal portion covering the first polymer and the second polymer, wherein the second metal portion is electrically connected to the first metal portion.
